(19) United States
(12) Patent Application Publication
(10) Pub. No.: US 2018/0366358 A1
(43) Pub. Date: Dec. 20, 2018

(54) SEMICONDUCTOR PROCESSING EQUIPMENT ALIGNMENT APPARATUS AND METHODS USING REFLECTED LIGHT MEASUREMENTS

(71) Applicant: Samsung Electronics Co., Ltd., Suwon-si (KR)

(72) Inventors: Jin Shin, Suwon-si (KR); Seung Jae Lee, Hwaseong-si (KR); Sang Geun Park, Hwaseong-si (KR); Dong Seok Baek, Hwaseong-si (KR)

(21) Appl. No.: 15/789,082

(22) Filed: Oct. 20, 2017

(30) Foreign Application Priority Data
Jun. 14, 2017 (KR) 10-2017-0074709

(51) Int. Cl. H01L 21/68; C23C 16/52; G01B 11/14; G01B 11/27

(52) U.S. Cl. CPC H01L 21/681; G01B 11/272; G01B 11/14; C23C 16/52

(57) ABSTRACT

An apparatus for determining alignment of semiconductor processing equipment includes a sensing unit comprising a light emitting unit configured to irradiate a reflection substrate positioned opposite the apparatus and a light accepting unit configured to receive reflected light from the reflection substrate, a control unit configured to determine a gap between the sensing unit and the reflection substrate based on the received reflected light, and a wireless communication unit configured to transmit data regarding the determined gap to an electronic device. Methods of aligning semiconductor processing equipment and methods of fabricating semiconductor devices are also disclosed.

This application claims the benefit of Korean Patent Application No. 10-2017-0074709, filed on Jun. 14, 2017, in the Korean Intellectual Property Office, the disclosure of which is incorporated herein in its entirety by reference.

### BACKGROUND

### 1. Field

The present disclosure relates to semiconductor processing and, more particularly, to apparatus and methods for aligning and operating semiconductor processing equipment.

### 2. Description of the Related Art

A semiconductor process is a process very sensitive to the surrounding environment. For example, it is very important to keep the number of particles, ambient temperature/humidity, or the environment inside a chamber uniform. In particular, keeping the environment inside the chamber uniform may make it possible to uniformly maintain process temperature, gas flow pattern, and/or process by process uniformity.

Conventional gap measuring sensors have difficulty in precisely measuring narrow gaps, i.e., gaps of 10 mm or less, due to their low accuracy of about +/−25 μm on average, or low resolution. Herein above, the narrow gaps denote gaps of at least 10 mm or less. In addition, conventional gap measuring sensors may also have difficulty in measuring relatively broad gaps, may have low durability and may be unduly expensive.

### SUMMARY

Some examples of the present disclosure provide a gap measuring apparatus.

Some examples of the present disclosure also provide methods for aligning a semiconductor apparatus.

Some examples of the present disclosure also provide a method of manufacturing a semiconductor device.

However, examples of the present disclosure are not restricted to the one set forth herein. The above and other example of the present disclosure will become more apparent to one of ordinary skill in the art to which the inventive concept pertains by referencing the detailed description of the inventive concept given below.

According to some example embodiments of the present disclosure, an apparatus for determining alignment of semiconductor processing equipment includes a sensing unit comprising a light emitting unit configured to irradiate a reflection substrate positioned opposite the apparatus and a light accepting unit configured to receive reflected light from the reflection substrate, a control unit configured to determine a gap between the sensing unit and the reflection substrate based on the received reflected light, and a wireless communication unit configured to transmit data regarding the determined gap to an electronic device.

In some embodiments, the control unit may be configured to identify the gap using a lookup table. The lookup table may include information about first reflected light at a known first gap and information about second reflected light at a known second gap. In further embodiments, the lookup table may include information about third reflected light at a known third gap and information about fourth reflected light at a known fourth gap for a reflection substrate having first material properties and information about fifth reflected light at a known fifth gap and information about sixth reflected light at a known sixth gap for a reflection substrate having second material properties.

According to some embodiments, the light may be infrared light, and the light accepting unit may include a phototransistor. In some embodiments, the control unit may be configured to generate a digital value corresponding to the determined gap using an analog-to-digital converter (ADC) and to transmit the digital value the wireless communication unit. In some embodiments, the semiconductor processing equipment may include a wafer support and the apparatus may have a wafer form factor and may be configured to be mounted on the support.

In further embodiments, the sensing unit may include at least three sensors.

Further embodiments provide methods including providing a gap measuring apparatus on a support in a semiconductor processing apparatus, irradiating a reflection substrate opposite the gap measuring apparatus using a light emitting unit of the gap measuring apparatus, receiving light reflected by the reflection substrate at a light accepting unit of the gap measuring apparatus, determining a gap between the reflection substrate and the gap measuring apparatus based on the reflected light, wirelessly transmitting information about the determined gap from the gap measuring apparatus to an electronic device, and adjusting an alignment between the support and the reflection substrate based on the wirelessly transmitted information about the determined gap. In some embodiments, the methods may further include displaying information about the determined gap on a display device responsive to the wirelessly transmitted information about the determined gap. The electronic device may adjust the alignment based on the wirelessly transmitted information.

Still further embodiments provide methods of manufacturing a semiconductor device. The methods include providing a gap measuring apparatus on a support in a semiconductor processing apparatus, irradiating a reflection substrate opposite the gap measuring apparatus using a light emitting unit of the gap measuring apparatus, receiving light reflected by the reflection substrate at a light accepting unit of the gap measuring apparatus, determining a gap between the reflection substrate and the gap measuring apparatus based on the reflected light, wirelessly transmitting information about the determined gap from the gap measuring apparatus to an electronic device, adjusting an alignment between the support and the reflection substrate based on the wirelessly transmitted information about the determined gap, loading a wafer on the aligned support, and processing the loaded wafer in the semiconductor processing apparatus.

### BRIEF DESCRIPTION OF THE DRAWINGS

These and/or other aspects will become apparent and more readily appreciated from the following description of some examples of the present disclosure, taken in conjunction with the accompanying drawings in which:

FIG. 1 illustrates a gap measuring apparatus 100 according to some examples of the present disclosure.

FIG. 2 illustrates the type of a gap measuring apparatus 200 according to some examples of the present disclosure.

FIG. 3A illustrates the placement of a sensing unit 310 of a gap measuring apparatus 300 according to some examples of the present disclosure.

FIG. 3B illustrates another placement of a sensing unit 311 of a gap measuring apparatus 301 according to some examples of the present disclosure.

FIGS. 4A and 4B illustrate a lookup table according to some examples of the present disclosure.

FIGS. 5A and 5B illustrate a lookup table for reflection substrates having various material properties according to some examples of the present disclosure.

FIG. 6 illustrates a process of adjusting the alignment of a reflection substrate and a support using a gap measuring apparatus according to some examples of the present disclosure.

FIG. 7 illustrates a process in which an electronic device adjusts the alignment of a reflection substrate and a support using a gap measuring apparatus according to some examples of the present disclosure.

FIGS. 8A through 8C illustrate semiconductor apparatuses according to some examples of the present disclosure.

FIG. 9 illustrates a maintenance method of a semiconductor apparatus according to some examples of the present disclosure.

FIG. 10 illustrates a method of manufacturing a semiconductor device according to some examples of the present disclosure.

### DETAILED DESCRIPTION

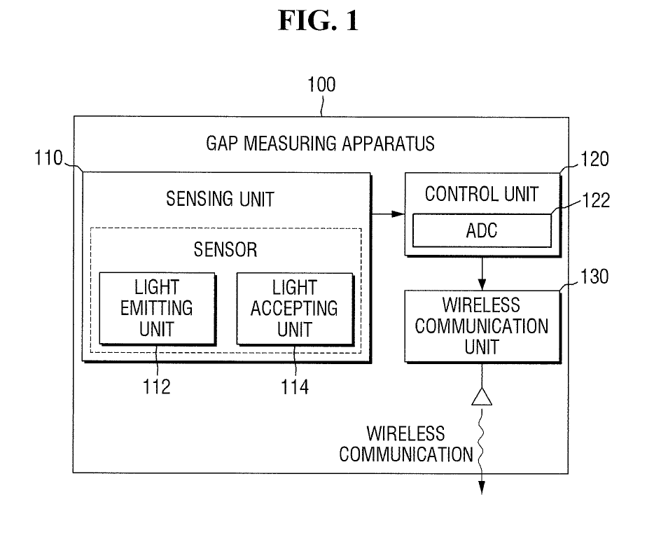

FIG. 1 illustrates a gap measuring apparatus 100 according to some examples of the present disclosure.

Referring to FIG. 1, the gap measuring apparatus 100 according to some examples of the present disclosure includes a sensing unit 110, a control unit 120, and a wireless communication unit 130.

The sensing unit 110 may include a light emitting unit 112 and a light accepting unit 114. The light emitting unit 112 may irradiate incident light to a reflection substrate, and the light accepting unit 114 may receive light reflected from the reflection substrate. In addition, the sensing unit 110 may transmit information about the reflected light received at the light accepting unit 114 to the control unit 120. The information about the reflected light may be, for example, information about the intensity of the reflected light. The information about the reflected light may be, for example, a current or voltage characteristic generated by the light accepting unit 114 receiving the reflected light.

The light emitting unit 112 may include a light emitting diode (LED), and incident light of the light emitting unit 112 may include, but not limited to, an infrared (IR) and/or laser light.

The light accepting unit 114 may include, but not limited to, a phototransistor (PT) and/or a photo diode (PD). For example, the incident light of the light emitting unit 112 may be infrared light, and the light accepting unit 114 may be a PT. The light accepting unit 114 may be disposed at an appropriate position according to the incident angle of the incident light irradiated by the light emitting unit 112. For ease of description, a combination including the light emitting unit 112 and the light accepting unit 114 will be referred to as a “sensor.”

The control unit 120 may include, but not limited to, an analog-to-digital converter (ADC) 122. The control unit 120 may calculate a gap between the reflection substrate and the sensing unit 110 using the information about the reflected light received from the sensing unit 110 and information in a lookup table. The lookup table may include information about the gap between the reflection substrate and the sensing unit 110, and information about reflected light corresponding to the gap. Details of the lookup table are described below.

For ease of description, the phrase “gap between the reflection substrate and the sensing unit” will be used interchangeably with the term “gap.”

The control unit 120 may transmit the calculated gap to the wireless communication unit 130. In particular, the control unit 120 may convert the calculated gap into a specific value using the ADC 122 and transmit the specific value to the wireless communication unit 130.

The wireless communication unit 130 may transmit the gap received from the control unit 120 to another electronic device through wireless communication, i.e., the electronic device may be an electronic device physically separated from the gap measuring apparatus 100. The wireless communication unit 130 may perform wireless communication such as, but not limited to, radio frequency (RF), Wi-Bro, high speed downlink packet access (HSDPA), WiFi, WiMax, ZIGBEE, Bluetooth, ultra-wide band, and/or near field communication (NFC). In the present disclosure, “another electronic device separated from the gap measuring apparatus 100” will be used interchangeably with “another electronic device” or “an electronic device.”

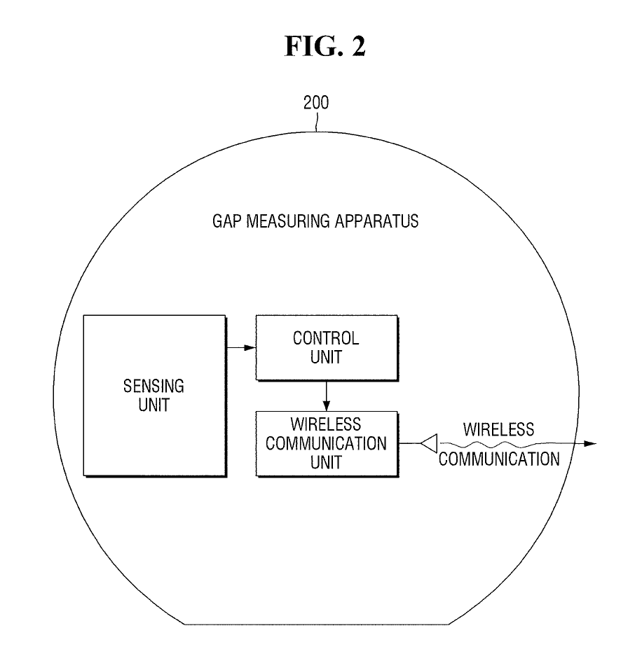

FIG. 2 illustrates a gap measuring apparatus 200 according to some examples of the present disclosure. Referring to FIG. 2, the gap measuring apparatus 200 according to some examples of the present disclosure may be in the form of a wafer. For example, the wafer-form gap measuring apparatus 200 may be directly mounted on a stage of a chemical vapor deposition (CVD) apparatus. For example, the wafer-form gap measuring apparatus 200 may be directly mounted on a chuck of a wafer bonding apparatus. For example, the wafer-form gap measuring apparatus 200 may be directly mounted on a chuck of a through-silicon via (TSV) apparatus. Some examples of how the gap measuring apparatus 200 according to some examples of the present disclosure is mounted on a semiconductor apparatus and operated are described below.

Although application examples of the wafer-form gap measuring apparatus 200 according to some examples of the present disclosure have been described above, the application of the wafer-type gap measuring apparatus 200 according to some examples of the present disclosure is not limited to the above application examples.

Also, although the gap measuring apparatus 200 is illustrated in FIG. 2 as the wafer-form, gap measuring apparatuses according to some examples of the present disclosure are not limited to a wafer form.

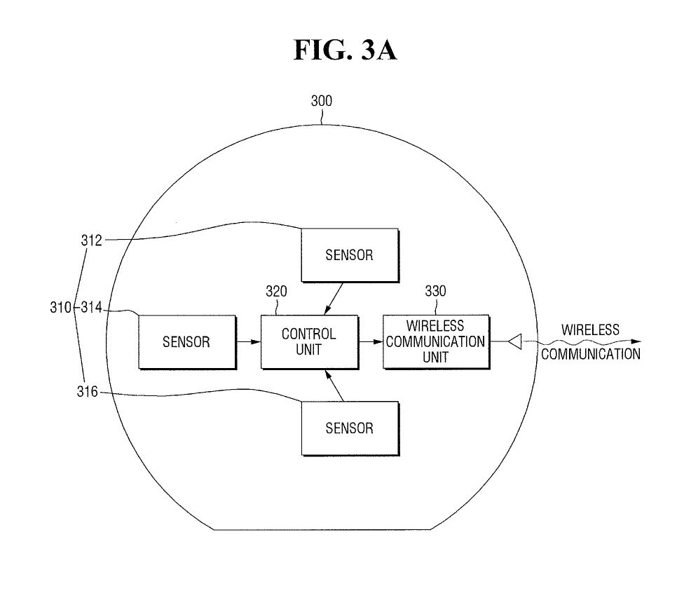

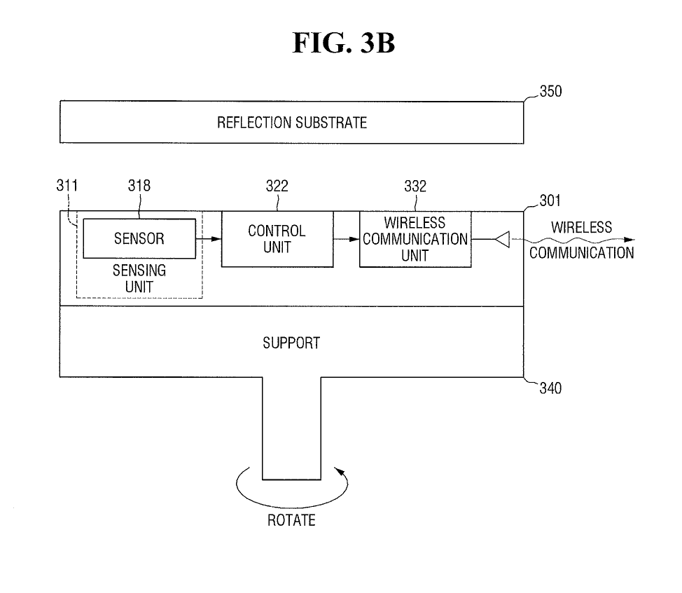

FIG. 3A illustrates the placement of a sensing unit 310 of a gap measuring apparatus 300 according to some examples of the present disclosure. Referring to FIG. 3A, the sensing unit 310 of the gap measuring apparatus 300 according to some examples of the present disclosure may include at least three sensors 312, 314 and 316. The three sensors 312, 314 and 316 may be arranged at angular intervals of about 120 degrees with respect to a center point of the gap measuring apparatus 300, but the present disclosure is not limited to this case.

For example, sensor A (312), sensor B (314), and sensor C (316) may be placed at position A, position B, and position C, respectively. A light accepting unit of sensor A (312) may transmit information about reflected light A to a control unit 320. Similarly, a light accepting unit of sensor B (314) may transmit information about reflected light B to the control unit 320 and a light accepting unit of sensor C (316) may transmit information about reflected light C to the control unit 320.

Herein, reflected light A may refer to light obtained after incident light irradiated by a light emitting unit of sensor A (312) at position A is reflected from a reflection substrate. In addition, reflected light B may refer to light obtained after incident light irradiated by a light emitting unit of sensor B (314) at position B is reflected from the reflection substrate. In addition, reflected light C may refer to light obtained after incident light irradiated by a light emitting unit of sensor C (316) at position C is reflected from the reflection substrate.

The control unit 320 may calculate gap A, gap B, and gap C by using the information about reflected light A, the information about reflected light B, the information about reflected light C, respectively, and in conjunction with a lookup table. The control unit 320 may also transmit information about gap A, gap B, and gap C to a wireless communication unit 330. Further, the control unit 320 may digitize the information about gap A, gap B, and gap C using an ADC, and transmit the digitized information about gaps A, B and C to the wireless communication unit 330.

Gap A may denote the gap between sensor A (312) at position A and the reflection substrate. In addition, gap B may denote the gap between sensor B (314) at position B and the reflection substrate. In addition, gap C may denote the gap between sensor C (316) at position C and the reflection substrate.

The wireless communication unit 330 may transmit information about gap A, gap B, and gap C to another electronic device through wireless communication.

The terms “A”, “B”, and “C” are used herein to distinguish one element or component from another element or component.

FIG. 3B illustrates another placement of a sensing unit 311 of a gap measuring apparatus 301 according to some examples of the present disclosure.

In FIG. 3B, a cross-sectional view is illustrated to effectively illustrate another placement of the sensing unit 311 according to some examples of the present disclosure. Referring to FIG. 3B, the sensing unit 311 of the gap measuring apparatus 301 according to some examples of the present disclosure may include one sensor 318. In addition, the gap measuring apparatus 301 may be provided on a support 340, which may be rotatable. The gap measuring apparatus 301 can measure a gap in real time while the support 340 is rotating.

Consequently, the gap measuring apparatus 301 can measure how a gap between the support 340 and a reflection substrate 350 changes while the support 340 is rotating. For example, the sensing unit 311 of the gap measuring apparatus 301 may transmit information about reflected light to a control unit 322 while the support 340 rotates, and the control unit 322 may calculate how the gap between the sensing unit 311 and the reflection substrate 350 changes while the support is rotating. The control unit 322 may transmit data regarding the gap to a wireless communication unit 332, and the wireless communication unit 332 may transmit the data to another electronic device.

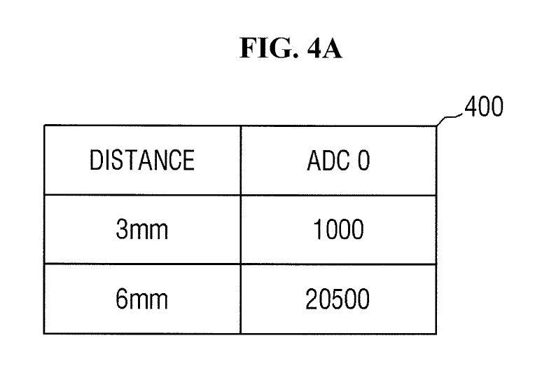

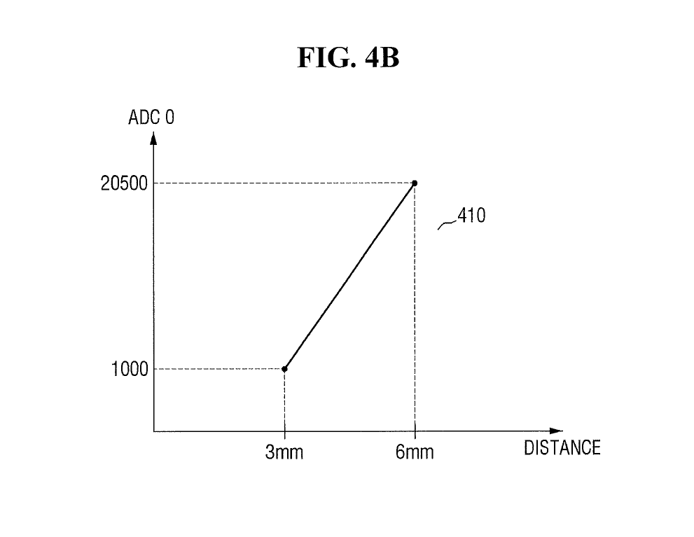

FIGS. 4A and 4B illustrate a lookup table according to some examples of the present disclosure.

Referring to FIGS. 4A and 4B, a lookup table of a gap measuring apparatus according to some examples of the present disclosure may correspond to a table 400 or a graph 410. The lookup table according to some examples of the present disclosure may include a gap DISTANCE and information ADC0 about reflected light. For a more clear description, reference will be made to the reference numerals of FIG. 1.

For example, when a control unit 120 (see FIG. 1) of a gap measuring apparatus 100 (see FIG. 1) according to some examples of the present disclosure calculates a gap, it refers to a gap corresponding to the information ADC0 (see FIGS. 4A and 4B) about the reflected light. When there is no gap corresponding to the information ADC0 (see FIGS. 4A and 4B) about the reflected light, the control unit 120 (see FIG. 1) according to some examples of the present disclosure may estimate the gap based on the relationship between the information ADC0 (see FIGS. 4A and 4B) about the reflected light and the gap included in the lookup table. Alternatively, the control unit 120 may approximate the gap corresponding to the information ADC0 about the reflected light by plotting the table 400 on a graph 410 as in FIG. 4B. In FIG. 4A and FIG. 4B, the information ADC0 (see FIGS. 4A and 4B) about the reflected light and a value of the information ADC0 of the gap measuring apparatus 100 (see FIG. 1) are a value selected arbitrarily for ease of description. Thus, it is apparent that the present disclosure is not limited to the information ADC0 (see FIGS. 4A and 4B) about the reflected light and the value of the information ADC0.

For example, the information ADC0 about the reflected light in FIGS. 4A and 4B may be a voltage or current value generated by a light accepting unit which receives the reflected light. Although only two gaps (DISTANCE in FIGS. 4A and 4B) are provided in the lookup table of FIG. 4A, this is merely for ease of description, and the present disclosure is not limited to the number of gaps.

Operations for forming the lookup table of FIGS. 4A and 4B will now be described. A reflection substrate and a sensing unit 110 (see FIG. 1) of the gap measuring apparatus 100 (see FIG. 1) may be spaced apart a first gap (3 mm in FIGS. 4A and 4B) that is already known. Then, a light emitting unit 112 (see FIG. 1) of the sensing unit 110 (see FIG. 1) may irradiate the reflection substrate, and light reflected from the reflection substrate may be received at a light accepting unit 114 (see FIG. 1). Herein, information ADC0 (see FIGS. 4A and 4B) about the reflected light received at the light accepting unit 114 (see FIG. 1) may be information (1000 in FIGS. 4A and 4B) about first reflected light at the first gap (3 mm in FIG. 4A and FIG. 4B).

The reflection substrate and the sensing unit 110 (see FIG. 1) of the gap measuring apparatus 100 (see FIG. 1) may be spaced apart a second gap (6 mm in FIGS. 4A and 4B) that is already known. The light emitting unit 112 (see FIG. 1) of the sensing unit 110 (see FIG. 1) may irradiate the reflection substrate, and light reflected from the reflection substrate may be received at the light accepting unit 114 (see FIG. 1). Herein, information ADC0 (see FIGS. 4A and 4B) about the reflected light received at the light accepting unit 114 (see FIG. 1) may be information (20500 in FIGS. 4A and 4B) about second reflected light at the second gap (6 mm in FIG. 4A and FIG. 4B). This process may be repeatedly performed for a third gap, a fourth gap, etc. to form the lookup table of FIG. 4A. As this process is repeated more times, the accuracy of the lookup table of FIG. 4A may be increased.

Herein, the first gap may denote a specific distance between the reflection substrate and the sensing unit 110, and the second gap may denote another specific distance between the reflection substrate and the sensing unit 110. In addition, at the first gap that is already known, when the light emitting unit 112 may irradiate incident light to the reflection substrate, light reflected from the reflection substrate may be referred to as the first reflected light. At the second gap that is already known, when the light emitting unit 112 may irradiate incident light to the reflection substrate, light reflected from the reflection substrate may be referred to as the second reflected light.

The graph 410 of FIG. 4B can be formed using the table 400 of FIG. 4A. The graph 410 of FIG. 4B can be formed by placing the information of the table 400 of FIG. 4A on the graph 410 and plotting approximation lines along those points.

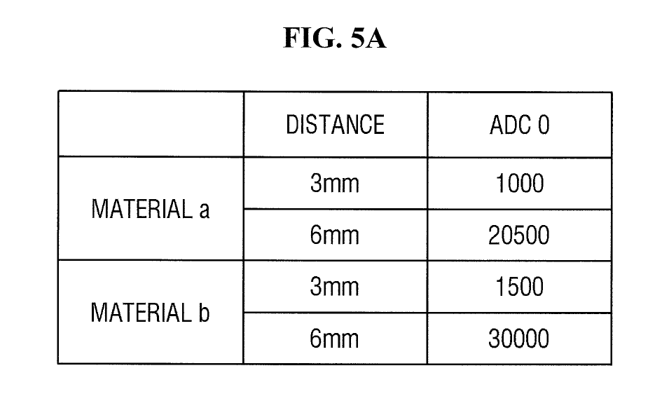

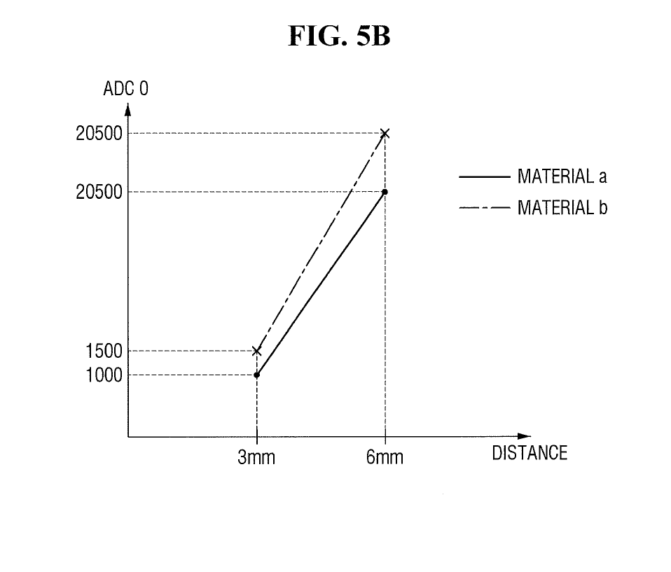

FIGS. 5A and 5B illustrate a lookup table for reflection substrates having various material properties according to some examples of the present disclosure.

For ease of description, the following description will be focused on differences from FIGS. 4A and 4B. For a more clear description, reference will be made to the reference numerals of FIG. 1. A gap measuring apparatus 100 (see FIG. 1) according to some examples of the present disclosure may measure gaps for reflection substrates having various material properties.

For example, a light emitting unit 112 (see FIG. 1) of a sensing unit 110 (see FIG. 1) of the gap measuring apparatus 100 (FIG. 1) irradiates incident light to a reflection substrate having first material properties MATERIAL a (see FIGS. 5A and 5B), and a light accepting unit 114 (see FIG. 1) receives light reflected from the reflection substrate having the first material properties MATERIAL a (see FIGS. 5A and 5B). Herein, a lookup table for the reflection substrate having the first material properties MATERIAL a (see FIGS. 5A and 5B) can be formed using the lookup table forming method mentioned in FIGS. 4A and 4B. Similarly, a lookup table for a reflection substrate having second material properties MATERIAL b (see FIGS. 5A and 5B) can be formed. In this way, lookup tables for reflection substrates having different material properties can be formed. By performing this process repeatedly, it is possible to form a lookup table for reflection substrates having various material properties. Herein, material properties refer to physical properties and encompass not only a difference in material characteristics but also the roughness of the surface of a reflection substrate.

A lookup table for reflection substrates having various material properties can be used to measure gaps between the sensing unit 110 (see FIG. 1) according to some examples of the present disclosure and reflection substrates having various material properties.

For example, a control unit 120 (FIG. 1) of the gap measuring apparatus 100 according to some examples of the present disclosure may calculate a gap between the sensing unit 110 (see FIG. 1) and the reflection substrate having the first material properties MATERIAL a (see FIGS. 5A and 5B) using the lookup table for the first material properties MATERIAL a (see FIGS. 5A and 5B). The control unit 120 (see FIG. 1) may calculate a gap between the sensing unit 110 (see FIG. 1) and the reflection substrate having the second material properties MATERIAL b (see FIGS. 5A and 5B) using the lookup table for the second material properties MATERIAL b (see FIGS. 5A and 5B).

For example, a gap between a shower head of a CVD apparatus and a sensing unit of a gap measuring apparatus may be calculated using a lookup table for material properties of the shower head. For example, a gap between an upper chuck of a wafer bonding apparatus and the sensing unit of the gap measuring apparatus may be calculated using a lookup table for material properties of the upper chuck. For example, a gap between a lower substrate of a TSV apparatus and the sensing unit of the gap measuring apparatus may be calculated using a lookup table for material properties of the lower substrate. The above embodiments are illustrative, and the present disclosure is not limited to these embodiments.

The terms “first,” “second,” etc. are used herein to distinguish one element or component from another element or component.

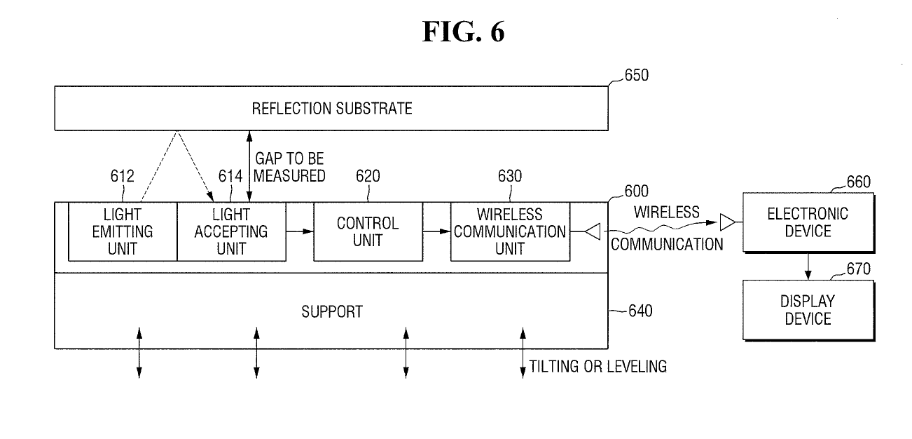

FIG. 6 illustrates a process of adjusting the alignment of a reflection substrate and a support using a gap measuring apparatus according to some examples of the present disclosure.

For simplicity, the following description will be focused on differences from FIGS. 1 through 5B. Referring to FIG. 6, a gap measuring apparatus 600 may be provided on a support 640. A light emitting unit 612 of the gap measuring apparatus 600 may irradiate incident light to a reflection substrate 650, and light reflected from the reflection substrate 650 may be received at a light accepting unit 614. The light accepting unit 614 may transmit information about the reflected light to a control unit 620, and the control unit 620 may calculate a gap using the information about the reflected light in conjunction with a lookup table. The control unit 620 may transmit data regarding the gap to a wireless communication unit 630. The wireless communication unit 630 may transmit the data regarding the gap to an electronic device 660.

The electronic device 660 may be a smartphone, a tablet computer, a wearable computing device, a laptop computer, a notebook computer, a mobile computing device, a cellular telephone, a handset, a messaging device, a server computer, a workstation, a distributed computing system, a multiprocessor system, and/or any other computing device configured to perform the functions described herein. The electronic device 660 may transmit the received data regarding the gap to a display device 670.

The display device 670 may be embodied as a monitor, a cellular phone, a graphical user interface (GUI), and/or various other types of commonly used output devices. The display device 670 may output the received data regarding the gap to a display.

Based on the data regarding the gap output from the display device 670, a user may adjust the alignment of the support 640 and the reflection substrate 650 by tilting or leveling the support 640.

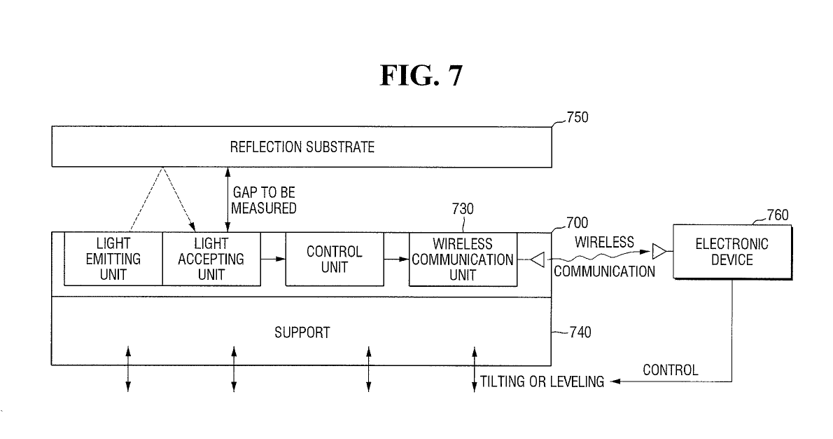

FIG. 7 illustrates a process in which an electronic device adjusts the alignment of a reflection substrate and a support using a gap measuring apparatus according to some examples of the present disclosure.

For simplicity, the following description will be focused on differences with respect to FIGS. 1 through 6. Repeat descriptions of items in FIG. 7 denoted by reference numerals previously described are omitted. Referring to FIG. 7, an electronic device 760 may receive data regarding a gap from a wireless communication unit 730 of a gap measuring apparatus 700. Based on the received data regarding the gap, the electronic device 760 may adjust the alignment of a support 740 and a reflection substrate 750 by tilting or leveling the support 740. It illustrates that the process of the alignment can be automatic.

As an example, operations for adjusting alignment using a gap measuring apparatus according to some examples of the present disclosure will now be described. In particular, a situation in which a gap between a sensing unit of a gap measuring apparatus according to some examples of the present disclosure and a reflection substrate is adjusted to 5 mm will be described as an example with reference to FIGS. 3A, 3B, 6 and 7.

Referring to FIGS. 3A, 6 and 7, in some embodiments, sensor A 312 (see FIG. 3A), sensor B 314 (see FIG. 3A), and sensor C 316 (see FIG. 3A) may measure gap A, gap B, and gap C, respectively. For example, a control unit 620 (see FIG. 6) may calculate gap A as 5.1 mm, gap B as 5.0 mm and gap C as 4.9 mm and transmit information about the gaps A, B and C to a wireless communication unit 630 (see FIG. 6). The wireless communication unit 630 (see FIG. 6) may transmit the received information to an electronic device 660 (see FIG. 6), and the electronic device 660 (see FIG. 6) may output the received information about the gaps A, B and C to a display device 670 (see FIG. 6). Then, a user may adjust the alignment of a reflection substrate and a support based on gap A, gap B and gap C displayed on the display device 670 (see FIG. 6). For example, the user may adjust the alignment of the reflection substrate 650 and the support 640 by tilting the support 640 upward by 0.1 mm at position A and tilting the support 640 downward by 0.1 mm at position C. Alternatively or in combination with adjustment by the user, the electronic device 760 (see FIG. 7) may adjust the alignment of the reflection substrate 750 and support 740 by controlling tilting the support 740.

Referring to FIGS. 3B, 6 and 7, in some embodiments, a sensor 318 (see FIG. 3B) may measure a gap while a support 340 (see FIG. 3B) is rotating. The gap may be continuously measured while the support 340 (see FIG. 3B) is rotating or may be measured discretely. Information about the measured gap may be output to a display device 670 (see FIG. 6), and a user may adjust alignment by tilting or leveling the support 340 with reference to the information about the continuous or discrete gap displayed on the display device 670 (see FIG. 6). Alternatively or in combination with adjustment by the user, an electronic device 760 (see FIG. 7) may adjust the alignment by controlling such tilting.

The numerical values mentioned above are only exemplary numerical values arbitrarily selected in order to more clearly explain the alignment process according to some examples of the present disclosure, and it is apparent that the present disclosure is not limited to these exemplary numerical values.

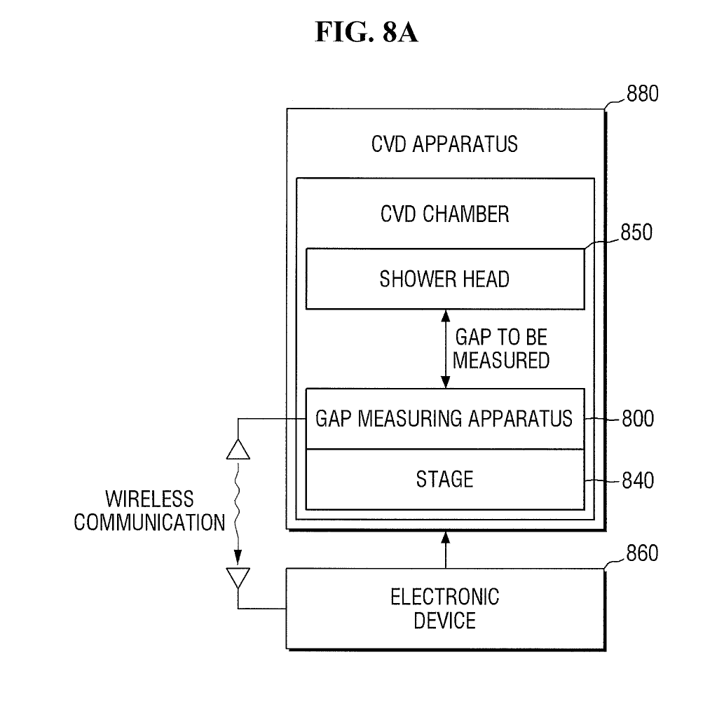

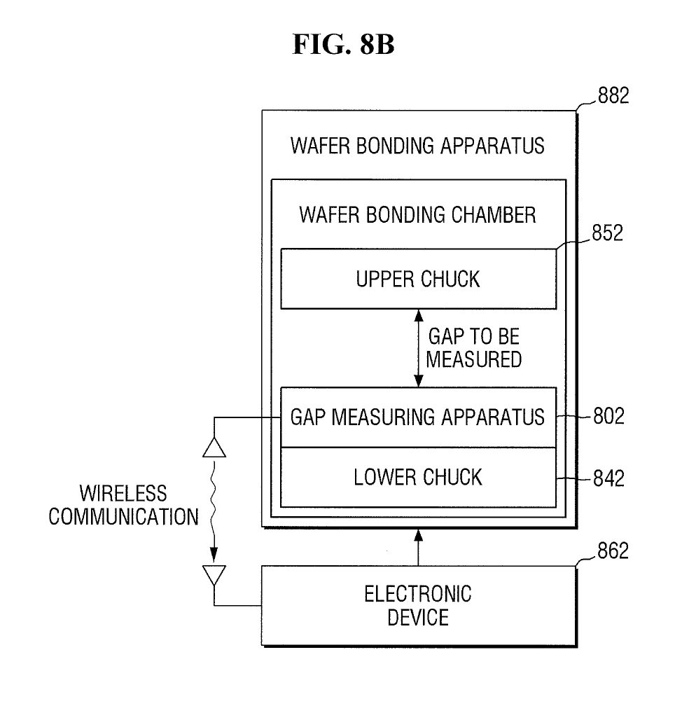

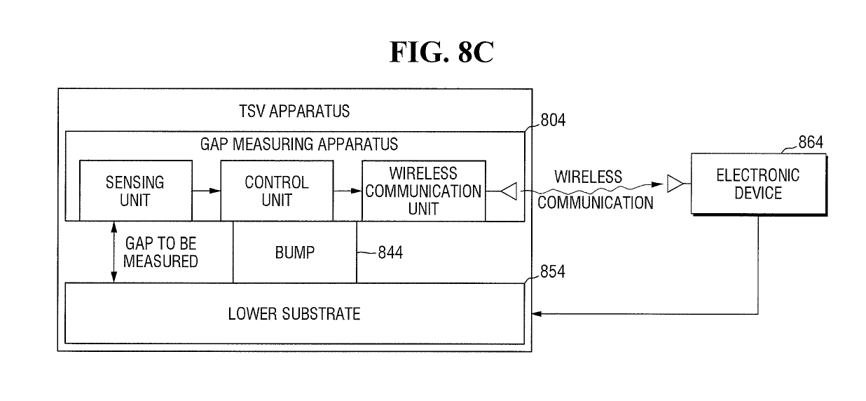

FIGS. 8A through 8C illustrate semiconductor apparatuses according to some examples of the present disclosure.

FIG. 8A illustrates a CVD apparatus 880 according to some examples of the present disclosure. For simplicity, the following description will be focused on differences from FIGS. 1 through 7. A gap measuring apparatus 800 may be any one of the gap measuring apparatuses described above with reference to FIGS. 1 through 7.

Referring to FIG. 8A, a chamber of the CVD apparatus 880 may include a shower head 850 and a stage 840. The reflection substrate and the support described above with reference to FIGS. 1 through 7 may be the shower head 850 and the stage 840, respectively. An electronic device 860 may be included in an electronic device that controls the CVD apparatus 880. In some embodiments, the electronic device 860 may include another electronic device provided outside the CVD apparatus 880 to adjust the alignment of the shower head 850 of the CVD apparatus 880 and a sensing unit of the gap measuring apparatus 800 provided on the stage 840.

FIG. 8B illustrates a wafer bonding apparatus 882 according to some examples of the present disclosure. For simplicity, the following description will be focused on differences from FIGS. 1 through 7. A gap measuring apparatus 802 may be any one of the gap measuring apparatuses described above with reference to FIGS. 1 through 7. Referring to FIG. 8B, a chamber of the wafer bonding apparatus 882 may be an upper chuck 852 and a lower chuck 842. The reflection substrate and the support described above with reference to FIGS. 1 through 7 may be the upper chuck 852 and the lower chuck 842, respectively. An electronic device 862 may be included in an electronic device that controls the wafer bonding apparatus 882. In some embodiments, the electronic device 862 may include another electronic device provided outside the wafer bonding apparatus 882 to adjust the alignment of the upper chuck 852 of the wafer bonding apparatus 882 and a sensing unit of the gap measuring apparatus 802 provided on the lower chuck 842.

FIG. 8C illustrates a TSV apparatus 884 according to some examples of the present disclosure. For simplicity, the following description will be focused on differences from FIGS. 1 through 7. A gap measuring apparatus 804 may be any one of the gap measuring apparatuses described above with reference to FIGS. 1 through 7.

Referring to FIG. 8C, a chamber of the TSV apparatus 884 may include a lower substrate 854 and a bump 844. The reflection substrate and the support described above with reference to FIGS. 1 through 7 may be the lower substrate 854 and the bump 844, respectively. An electronic device 864 may be included in an electronic device that controls the TSV apparatus 884. In some embodiments, the electronic device 864 may include another electronic device provided outside the TSV apparatus 884 to adjust the alignment of the lower substrate 854 of the TSV apparatus 884 and a sensing unit of the gap measuring apparatus 804 provided on the bump 844.

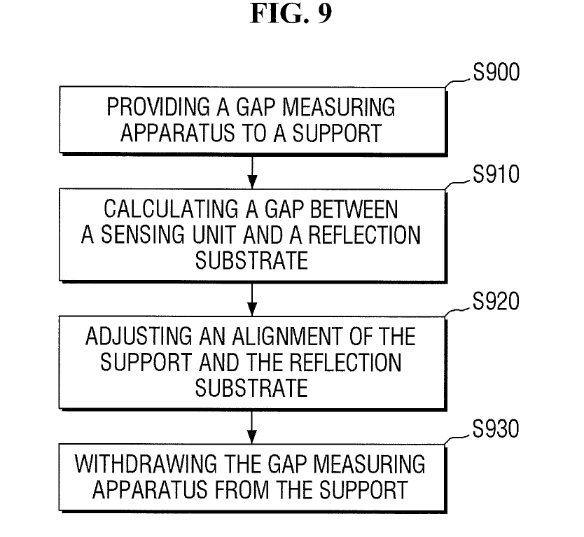

FIG. 9 illustrates maintenance operations method of a semiconductor apparatus according to some examples of the present disclosure.

For simplicity, the following description will be focused on differences from FIGS. 1 through 8C. Referring to FIG. 9, a gap measuring apparatus according to some examples of the present disclosure is provided on a support (block S900). A gap between a sensing unit of the gap measuring apparatus and a reflection substrate is calculated (block S910). The alignment of the support and the reflection substrate is adjusted (block S920). The gap measuring apparatus is withdrawn from the support (block S930). The semiconductor apparatus maintenance method according to FIG. 9 can be used to maintain a chamber of a semiconductor apparatus in a uniform environment before or after a process, before or after cleaning, or before or after the replacement of parts in the chamber of the semiconductor apparatus.

For example, the providing of the gap measuring apparatus according to some examples of the present disclosure on the support may be an operation of attaching the gap measuring apparatus to the support. For example, the providing of the gap measuring apparatus according to some examples of the present disclosure on the support may be an operation of mounting the gap measuring apparatus on the support. For example, the providing of the gap measuring apparatus according to some examples of the present disclosure on the support may be an operation of mounting the gap measuring apparatus on the support and fixing the gap measuring apparatus to the support using another medium. The providing of the gap measuring apparatus according to some examples of the present disclosure on the support can be performed in any of a number of different ways.

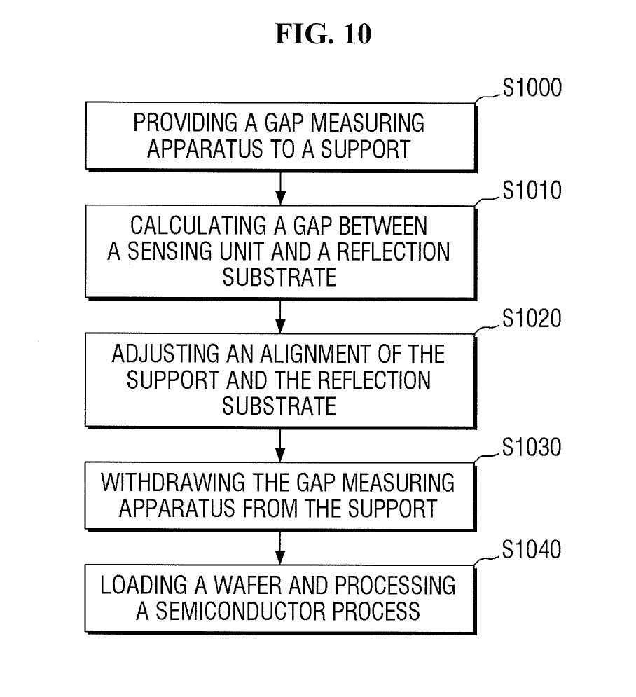

FIG. 10 illustrates operations for manufacturing a semiconductor device according to some examples of the present disclosure. For simplicity, the following description will be focused on differences from FIGS. 1 through 8C. Referring to FIG. 10, a gap measuring apparatus according to some examples of the present disclosure is provided on a support (block S1000). A gap between a sensing unit of the gap measuring apparatus and a reflection substrate is calculated (block S1010). The alignment of the support and the reflection substrate is adjusted (block S1020). The gap measuring apparatus is withdrawn from the support (block S1030). Then, a wafer is loaded, and a semiconductor process is performed (block S1040).

While the present disclosure has been particularly shown and described with reference to exemplary embodiments thereof, it will be understood by those of ordinary skill in the art that various changes in form and details may be made therein without departing from the spirit and scope of the present disclosure as defined by the following claims. It is therefore desired that the present embodiments be considered in all respects as illustrative and not restrictive, reference being made to the appended claims rather than the foregoing description to indicate the scope of the present disclosure.

1. An apparatus for determining alignment of semiconductor processing equipment, the apparatus comprising:
a sensing unit comprising a light emitting unit configured to irradiate a reflection substrate positioned opposite the apparatus and a light accepting unit configured to receive reflected light from the reflection substrate;
a control unit configured to determine a gap between the sensing unit and the reflection substrate based on the received reflected light; and
a wireless communication unit configured to transmit data regarding the determined gap to an electronic device.

2. The apparatus of claim 1, wherein the control unit identifies the gap using a lookup table.

3. The apparatus of claim 2, wherein the lookup table comprises information about first reflected light at a known first gap and information about second reflected light at a known second gap.

4. The apparatus of claim 3, wherein the lookup table comprises:
information about third reflected light at a known third gap and information about fourth reflected light at a known fourth gap for a reflection substrate having first material properties; and
information about fifth reflected light at a known fifth gap and information about sixth reflected light at a known sixth gap for a reflection substrate having second material properties.

5. The apparatus of claim 1, wherein the light is infrared light, and wherein the light accepting unit comprises a phototransistor.

6. The apparatus of claim 1, wherein the control unit is configured to generate a digital value corresponding to the determined gap using an analog-to-digital converter (ADC) and to transmit the digital value the wireless communication unit.

7. The apparatus of claim 1, wherein the semiconductor processing equipment comprises a wafer support and wherein the apparatus has a wafer form factor and is configured to be mounted on the support.

8. The gap measuring apparatus of claim 1, wherein the sensing unit comprises at least three sensors.

9.-20. (canceled)
